(19) United States
(12) Patent Application Publication
(10) Pub. No.: US 2006/0043553 A1
(43) Pub. Date: Mar. 2, 2006

(54) Chip package having a heat spreader and method for packaging the same

(75) Inventors: Ching Hsu Yang, Taichung City (TW); Chun En Huang, Renwu Township (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: ADVANCED SEMICONDUCTOR ENGINEERING, INC., Koahsiung (TW)

(21) Appl. No.: 11/217,612

(22) Filed: Sep. 2, 2005

(30) Foreign Application Priority Data
Sep. 2, 2004 (TW) 093126581

(51) Int. Cl. H01L 23/02

(52) U.S. Cl. 257/678

(57) ABSTRACT

A chip package mainly includes a substrate, a stiffener, a chip, a thermal interface material (TIM) and a heat spreader. The stiffener is disposed on the substrate and has a receiving portion. The chip is disposed on the substrate. The thermal interface material (TIM) is formed on a surface of the chip. The heat spreader has a resilient-buckling portion, which is snapped into the receiving portion of the stiffener, whereby the heat spreader can contact the thermal interface material (TIM), the bond line thickness of the thermal interface material between the chip and the heat spreader can be controlled, and the heat spreader is prevented from sliding during a packaging process.

This application claims the priority benefit of Taiwan Patent Application Serial Number 093126581, filed Sep. 2, 2004, the full disclosure of which is incorporated herein by reference.

### BACKGROUND OF THE INVENTION

1. Field of the Invention

The present invention relates to a chip package having a heat spreader, and more particularly, to a chip package and a packaging method for controlling the bond line thickness (BLT) of a thermal interface material between a chip and a heat spreader

2. Description of the Related Art

In order to further dissipate the heat form a chip, a conventional chip package is provided with a heat spreader and a thermal interface material (TIM). Referring to FIG. 1, a chip package 100 includes a substrate 110, a stiffener 120, a chip 130, a thermal interface material 140 and a heat spreader 150. The stiffener 120 is disposed on the substrate 110 and has an opening 121. The chip 130 is accommodated in the opening 121 of the stiffener 120 and is connected to the substrate 110 via a plurality of bumps 131. The gap between the chip 130 and the substrate 110 maintained by bumps 131 is filled with an underfill 132. The thermal interface material 140 is formed between the chip 130 and the heat spreader 150. The heat spreader 150 is thermally coupled to the chip 130 by means of the thermal interface material 140, and is mounted to the stiffener 120 by means of a thermosetting adhesive 160. When the thermosetting adhesive 160 is cured, the thermal interface material 140 is also heated. The bond line thickness (BLT) of the thermal interface material 140 between the chip 130 and the heat spreader 150, the contacting area between the thermal interface material 140 and the heat spreader 150, and the contacting area between the thermal interface material 140 and the chip 130 cannot be controlled, because the thermal interface material 140 expands when hot and shrinks when cold. Thus, the heat dissipation of the conventional chip package is not so good as desired. Moreover, it easily results in delamination between the heat spreader 150 and the chip 140, and thus the heat spreader 150 might drop off from the chip 140. In order to control the bond line thickness (BLT) of the thermal interface material 140 between the chip 130 and the heat spreader 150, a special clamping device 10 is provided in the packaging process for upward and downward clamping the chip package 100 and a conveyable carrier 20 (referring to FIG. 2), and then the chip package 100 is cured. However, when the clamping device 10 clamps the chip package 100 and the conveyable carrier 20, it is easy that the clamping device 10 moves the heat spreader 150 or the chip package 100 escapes from the conveyable carrier 20 because of abnormal operation. Furthermore, the clamping and unclamping steps of the clamping device 10 will also increase the manufacturing cost for the package.

Taiwan Patent Publication Number 567563, entitled “Semiconductor Chip Package And Method For Manufacturing The Same”, discloses a conventional semiconductor chip package for improving the heat dissipation. The semiconductor chip package includes a substrate, a stiffening ring, a chip, a polymer layer and a heat spreader. The stiffening ring is disposed on the substrate. The chip has an active surface and includes a plurality of bumps formed on the active surface. The chip is mounted to the substrate via a plurality of bumps. The polymer layer is disposed between the chip and the heat spreader, and a thermal conductive adhesive is disposed on the stiffening ring. Similarly, according to the above-mentioned semiconductor chip package, the bond line thickness (BLT) of the polymer layer between the chip and the heat spreader cannot be controlled, and the spreader can also slide before the thermal conductive adhesive is cured.

Accordingly, there exists a need for a chip package having a heat spreader to solve the above-mentioned disadvantages.

### SUMMARY OF THE INVENTION

It is an object of the present invention to provide a chip package, including a substrate, a stiffener, a chip, a thermal interface material and a heat spreader. The stiffener and the chip are disposed on an upper surface of the substrate, and the stiffener has a receiving portion. The thermal interface material is formed between the chip and the heat spreader. The heat spreader includes a resilient-buckling portion, and is thermally coupled to the chip via the thermal interface material. The resilient-buckling portion of the heat spreader is snapped into the receiving portion of the stiffener, whereby the bond line thickness (BLT) of the thermal interface material between the chip and the heat spreader can be controlled, and the heat spreader is mounted so as to prevent the heat spreader from sliding during a packaging process.

It is another object of the present invention to provide a method for packaging the chip package, including the following steps of providing a substrate having an upper surface; disposing a stiffener on the upper surface of the substrate, wherein the stiffener has a receiving portion; disposing a chip on the upper surface of the substrate; forming a thermal interface material on a surface of the chip; providing a heat spreader having a bottom surface and including a resilient-buckling portion; and assembling the heat spreader and the stiffener by snapping the resilient-buckling portion of the heat spreader into the receiving portion of the stiffener, whereby the bottom surface of the heat spreader contacts the thermal interface material, the bond line thickness (BLT) of the thermal interface material between the chip and the heat spreader can be controlled, and the heat spreader is mounted so as to prevent the heat spreader from sliding during a packaging process.

According to a chip package of the present invention, the chip package includes a substrate, a stiffener, a chip, a thermal interface material and a heat spreader. The substrate has an upper surface. The stiffener is disposed on the upper surface of the substrate, and has a receiving portion. The chip is disposed on the upper surface of the substrate. The thermal interface material is formed on a surface of the chip, e.g. an active surface or a back surface, and the thermal interface material is formed between the chip and the heat spreader. The heat spreader has a bottom surface and includes a resilient-buckling portion projecting from the bottom surface. The resilient-buckling portion of the heat spreader is snapped into the receiving portion of the stiffener, thereby mounting the heat spreader, and further controlling the bond line thickness (BLT) of the thermal interface material between the chip and the heat spreader.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional schematic view of a chip package in the prior art.

FIG. 2 is a cross-sectional schematic view showing a clamping device for clamping a chip package in the prior art before a heat spreader is attached to the chip package.

FIG. 3 is a cross-sectional schematic view of a chip package having a heat spreader according to the first embodiment of the present invention.

FIG. 4 is a bottom plan schematic view of a heat spreader according to the first embodiment of the present invention.

FIGS. 5A to 5D are cross-sectional schematic views of a method for packaging a chip package having a heat spreader according to the first embodiment of the present invention.

FIG. 6 is a cross-sectional schematic view of a chip package having a heat spreader according to the second embodiment of the present invention.

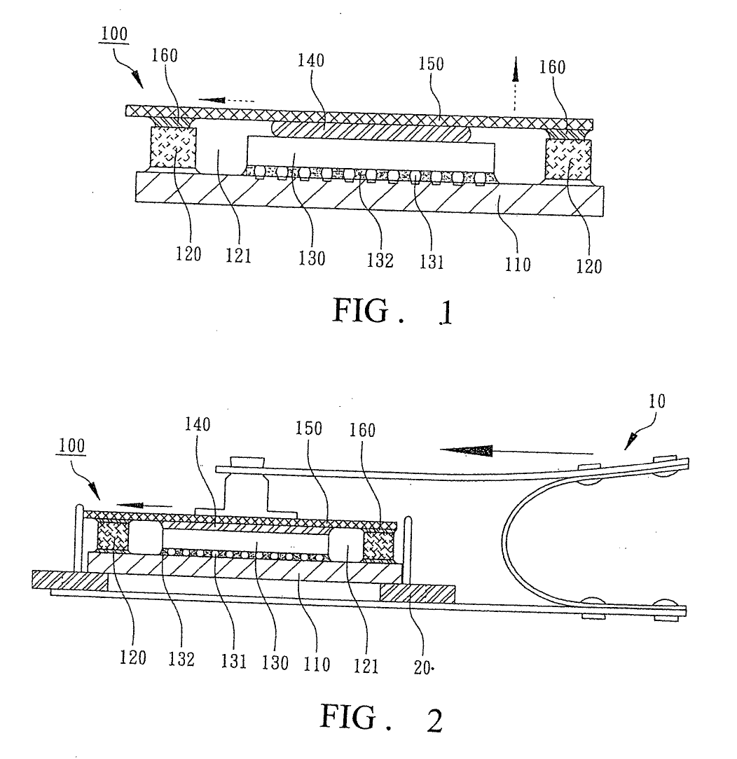

### DETAILED DESCRIPTION OF THE PREFERRED EMBODIMENT

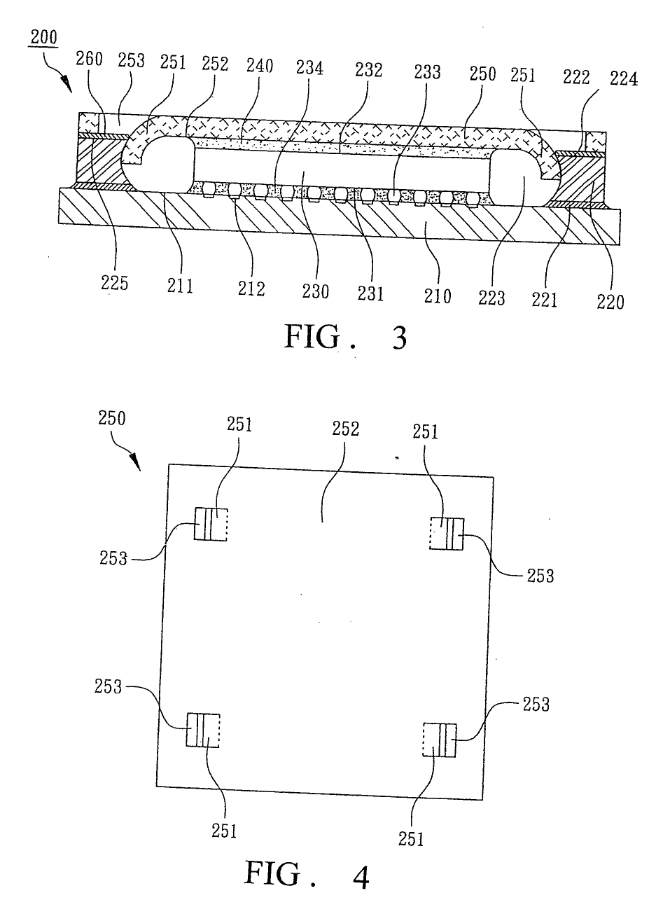

Referring to FIG. 3, it depicts a chip package 200 according to the first embodiment of the present invention. The chip package 200 includes a substrate 210, a stiffener 220, a chip 230, a thermal interface material (TIM) 240 and a heat spreader 250. The substrate 210 has an upper surface 211 and includes a plurality of bonding pads 212 formed on the upper surface 211, wherein the heat spreader 250 is resiliently snapped into the stiffener 220. Preferably, the substrate 210 is a build-up wiring substrate.

The stiffener 220 is attached on the upper surface 211 of the substrate 210 by means of an adhesive 221. The stiffener 220 has a receiving portion 222. The stiffener 220 can be a body of annular shape or bar-shaped bodies symmetrically disposed on the substrate 210. In this embodiment, the stiffener 220 is a body of annular shape and has an opening 223. Preferably, the opening 223 is rectangular and has a sidewall 224. The receiving portion 222 is formed on the sidewall 224 of the opening 223, preferably with arc-shaped concaves.

The chip 230 is disposed on the upper surface 211 of the substrate 210, and is accommodated in the opening 223 of the stiffener 220. Alternatively, when the stiffener 220 is bar-shaped bodies symmetrically disposed on the substrate 210, the chip 230 is disposed between the bar-shaped bodies (not shown). The chip 230 has an active surface 231 and a back surface 232 opposite to the active surface 231. In this embodiment, the chip 230 is a flip chip and includes a plurality of bumps 233 disposed on the active surface 231. The active surface 231 of the chip 230 faces the substrate 210, and the bumps 233 of the chip 230 are connected to the bonding pads 212 of the substrate 210. An underfill 234 seals the active surface 231 of the chip 230 and fills the gap between the substrate 210 and the chip 230.

The thermal interface material 240 is formed on a surface of the chip 230, e.g. the thermal interface material 240 is formed on the active surface 231 or the back surface 232 of the chip 230. In this embodiment, the bumps 233 disposed on the active surface 231 of the chip 230 are connected to the bonding pads 212 of the substrate 210, and thus the thermal interface material 240 is formed on the back surface 232 of the chip 230. The thermal interface material 240 can be a thermosetting resin having better thermally conductive property for conducting the heat from the chip 230 to the heat spreader 250.

The heat spreader 250 has a bottom surface 252 and includes a resilient-buckling portion 251 projecting from the bottom surface 252. Preferably, the heat spreader 250 is rectangular. In this embodiment, the resilient-buckling portion 251 of the heat spreader 250 is formed by a plurality of arc-shaped resilient pieces symmetrical to each other. The arc-shaped resilient pieces can be independent elements welded to the heat spreader 250 or be integrally formed by punching the heat spreader 250. Referring to FIG. 4, preferably, the resilient-buckling portion 251 and the heat spreader 250 are integrally formed, thereby decreasing the packaging cost of the heat spreader 250. In this embodiment, a plurality of U-shaped through holes 253 are symmetrically disposed in the heat spreader 250 by punching the heat spreader 250, and the remainder materials of the heat spreader 250 located in the U-shaped through holes 253 are punched and bent in the direction of the bottom surface 252, thereby forming the resilient-buckling portion 251 projecting from the bottom surface 252. Referring to FIG. 3, the resilient-buckling portion 251 of the heat spreader 250 can be resiliently snapped into the receiving portion 222 of the stiffener 220, whereby the bottom surface 252 of the heat spreader 250 contacts the thermal interface material 240. The material of the heat spreader 250 and the resilient-buckling portion 251 can be selected from one of the group consisting of copper, aluminum, and alloy thereof.

In this embodiment, a thermosetting adhesive 260 is disposed on a top surface 225 of the stiffener 220 for attaching the heat spreader 250 to the stiffener 220. The thermosetting adhesive 260 can be a thermosetting resin for providing strong adhesive force.

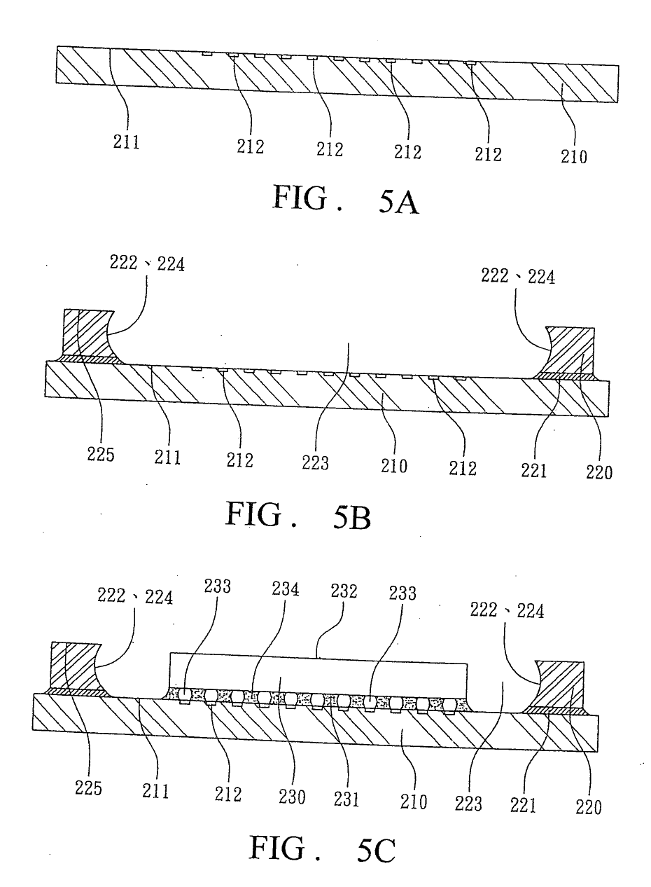

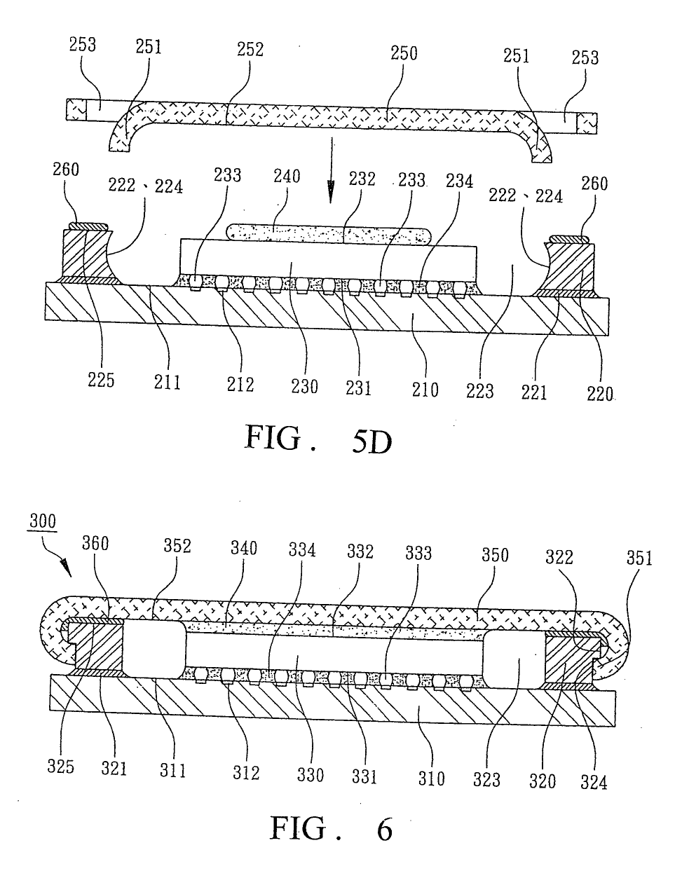

Referring to FIGS. 5A and 5D, they depict a method for packaging the chip package 200 of the present invention. Referring to FIG. 5A, a substrate 210 is firstly provided, wherein the substrate 210 has an upper surface 211 and includes a plurality of bonding pads 212 formed on the upper surface 211. Referring to FIG. 5B, a stiffener 220 is disposed on the upper surface 211 of the substrate 210. In this embodiment, the stiffener 220 is attached on the upper surface 211 of the substrate 210 by means of an adhesive 221. The stiffener 220 has a receiving portion 222 and an opening 223, wherein the receiving portion 222 is formed on a sidewall 224 of the opening 223, preferably with arc-shaped concaves. Referring to FIG. 5C, a chip 230 is disposed on an upper surface 211 of the substrate 210, wherein the chin 230 has an active surface 231 and a back surface 232 opposite to the active surface 231. In this embodiment, the chip 230 is a flip chip, the active surface 231 of the chip 230 faces the substrate 210, and bumps 233 of the chip 230 are connected to the bonding pads 212 of the substrate 210. Furthermore, the chip 230 is accommodated in the opening 223 of the stiffener 220, and an underfill 234 is provided for sealing the active surface 231 of the chip 230 and filling the gap between the substrate 210 and the chip 230. Referring to FIG. 5D, a thermal interface material 240 is formed on a surface of the chip 230. In this embodiment, the thermal interface material 240 is formed on the back surface 232 of the chip 230. A heat spreader 250 is provided, wherein the heat spreader 250 has a bottom surface 252 and includes a resilient-buckling portion 251. Then, the heat spreader 250 is snapped into the stiffener 220. In this embodiment, referring to FIG. 3 again, the resilient-buckling portion 251 of the heat spreader 250 can be resiliently snapped into the receiving portion 222 of the stiffener 220, whereby the bottom surface 252 of the heat spreader 250 contacts the thermal interface material 240, and the bond line thickness (BLT) of the thermal interface material 240 between the chip 230 and the heat spreader 250 can be controlled. In addition, before the heat spreader 250 is snapped into the stiffener 220, a thermosetting adhesive 260 is disposed a top surface 225 of the stiffener 220 for attaching the heat spreader 250 to the stiffener 220. Then, the heat spreader 250 is attached to the stiffener 220 by curing the thermosetting adhesive 260. Finally, the chip package 200 is formed by the above-mentioned packaging method.

According to the above-mentioned chip package 200, the resilient-buckling portion 251 of the heat spreader 250 can be resiliently snapped into the receiving portion 222 of the stiffener 220 for assembling the heat spreader 250 and the stiffener 220, thereby controlling the bond line thickness (BLT) of the thermal interface material 240 between the back surface 232 of the chip 230 and the bottom surface 252 of the heat spreader 250, and mounting the heat spreader 250 so as to prevent the heat spreader 250 from sliding during a packaging process.

In addition, the aspect the resilient-buckling portion is not used to limit the invention. The resilient-buckling portion 251 of the heat spreader 250 is not only arc-shaped resilient pieces for snapping the heat spreader 250 into the stiffener 220, but also can be buckling hooks or other buckling mechanism which can replace the resilient pieces. Referring to FIG. 6, it depicts a chip package 300 according to the second embodiment of the present invention. The chip package 300 includes a substrate 310, a stiffener 320, a chip 330, a thermal interface material (TIM) 340 and a heat spreader 350. The substrate 310 has an upper surface 311 and includes a plurality of bonding pads 312 formed on the upper surface 311.

The stiffener 320 is attached on the upper surface 311 of the substrate 310 by means of an adhesive 321. The stiffener 320 has a receiving portion 322. Preferably, the stiffener 320 is a body of annular shape and has an opening 323 and an outward sidewall 324. In this embodiment, the receiving portion 322 can has a plurality of flanges or buckling grooves formed on the outward sidewall 324, wherein the heat spreader 350 can be snapped into the flange or buckling groove.

The chip 330 is disposed on the upper surface 311 of the substrate 310, and is accommodated in the opening 323 of the stiffener 320. The chip 330 has an active surface 331 and a back surface 332 opposite to the active surface 331. In this embodiment, the chip 330 is a flip chip and includes a plurality of bumps 333 disposed on the active surface 331. The bumps 333 of the chip 330 are connected to the bonding pads 312 of the substrate 310. An underfill 334 seals the active surface 331 of the chip 330 and fills the gap between substrate 310 and the chip 330.

The thermal interface material 340 is formed on a surface of the chip 330. The bumps 333 disposed on the active surface 331 of the chip 330 are connected to the bonding pads 312 of the substrate 310, and thus the thermal interface material 340 is formed on the back surface 332 of the chip 330.

The heat spreader 350 has a bottom surface 352 and includes a resilient-buckling portion 351. In this embodiment, the resilient-buckling portion 351 can has a plurality of buckling hooks. The resilient-buckling portion 351 is located around the heat spreader 350 and projects from the bottom surface 352. Preferably, the resilient-buckling portion 351 and the heat spreader 350 are integrally formed, and the buckling hooks can be formed by bending a side of the heat spreader 350 in the direction of the center of the bottom surface 352. The resilient-buckling portion 351 of the heat spreader 350 can be resiliently snapped into the receiving portion 322 of the stiffener 320 for assembling the heat spreader 350 and the stiffener 320. Furthermore, the heat spreader 350 is thermally coupled to the back surface 332 of the chip 330 via the thermal interface material 340. Preferably, a thermosetting adhesive 360 is disposed on a top surface 325 of the stiffener 320 for attaching the heat spreader 350 to the stiffener 320.

According to the above-mentioned chip package 300, the resilient-buckling portion 351 of the heat spreader 350 is resiliently snapped into the receiving portion 322 of the stiffener 320 for assembling the heat spreader 350 and the stiffener 320, whereby the bottom surface 352 of the heat spreader 350 contacts the thermal interface material 340 formed on the back surface 332 of the chip 330, the bond line thickness (BLT) of the thermal interface material 340 between the chip 330 and the heat spreader 350 can be controlled, and the heat spreader 350 is mounted so as to prevent the heat spreader 350 from sliding during a packaging process.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A chip package, comprising:
a substrate having an upper surface;
a stiffener disposed on the upper surface of the substrate, and having a receiving portion;
a chip disposed on the upper surface of the substrate and having a surface;
a thermal interface material formed on the surface of the chip; and
a heat spreader snapped into the stiffener, having a bottom surface, and including a resilient-buckling portion, wherein the resilient-buckling portion of the heat spreader is snapped into the receiving portion of the stiffener, whereby the bottom surface of the heat spreader contacts the thermal interface material.

2. The chip package as claimed in claim 1, wherein the resilient-buckling portion has a plurality of resilient pieces.

3. The chip package as claimed in claim 2, wherein the resilient pieces are formed on the bottom surface of the heat spreader.

4. The chip package as claimed in claim 2, wherein the resilient pieces are arc-shaped resilient pieces.

5. The chip package as claimed in claim 2, wherein the stiffener has an opening having a sidewall, the receiving portion of the stiffener is formed on the sidewall, and the resilient pieces are snapped into the receiving portion.

6. The chip package as claimed in claim 5, wherein the receiving portion of the stiffener is an arc-shaped concave.

7. The chip package as claimed in claim 1, wherein the resilient-buckling portion is a plurality of buckling hooks.

8. The chip package as claimed in claim 7, wherein the buckling hooks are located around the heat spreader.

9. The chip package as claimed in claim 7, wherein the receiving portion of the stiffener is formed on an outward sidewall of the stiffener, and the buckling hooks are snapped into the receiving portion.

10. The chip package as claimed in claim 9, wherein the receiving portion of the stiffener has a plurality of flanges.

11. The chip package as claimed in claim 9, wherein the receiving portion of the stiffener has a plurality of buckling grooves.

12. The chip package as claimed in claim 1, wherein the surface of the chip is an active surface.

13. The chip package as claimed in claim 1, wherein the surface of the chip is a back surface.

14. The chip package as claimed in claim 1, wherein the resilient-buckling portion and the heat spreader are integrally formed.

15. The chip package as claimed in claim 1, wherein the heat spreader includes a plurality of through holes, and the resilient-buckling portion is formed in the through holes, and the resilient-buckling portion projects from the bottom surface of the heat spreader.
